(19) United States
(12) Patent Application Publication
(10) Pub. No.: US 2026/0096482 A1
(43) Pub. Date: Apr. 2, 2026

(54) INTEGRATED CIRCUIT ASSEMBLY INCLUDING INTERPOSER BETWEEN STACKED DIE AND RELATED METHODS

(71) Applicant: Eagle Technology, LLC, Melbourne, FL (US)

(72) Inventors: Scott G. RAUSCHER, Fairfax, VA (US); Matthew J. BAUER, Melbourne, FL (US); Jason THOMPSON, Melbourne, FL (US); Louis J. RENDEK, JR., Melbourne, FL (US)

(21) Appl. No.: 19/082,248

(22) Filed: Mar. 18, 2025

Related U.S. Application Data
(63) Continuation-in-part of application No. 18/900,184, filed on Sep. 27, 2024.

(51) Int. Cl. H01L 25/16; G02B 6/42; H01L 23/46; H01L 23/498; H01L 23/535; H01L 25/18

(52) U.S. Cl. CPC H10W 90/00; G02B 6/4268; H10W 20/20; H10W 40/40; H10W 70/635; H10W 70/65; H10W 90/701

(57) ABSTRACT

An integrated circuit (IC) assembly may include a substrate and a plurality of IC die coupled to the substrate, which includes a bottom layer and a top layer coupled thereto and defining a heat exchange fluid chamber therebetween. A plurality of dielectric pillars extend within the heat exchange fluid chamber between the bottom layer and the top layer. A heat exchange fluid is within the heat exchange fluid chamber, and a wick structure within the heat exchange fluid chamber moves the heat exchange fluid in a liquid phase into the heat exchange fluid chamber. A plurality of electrically conductive through-vias extend within respective ones of the plurality of dielectric pillars and are exposed on outer surfaces of the bottom layer and the top layer. An optical waveguide layer is above the top layer.

### PRIORITY APPLICATION(S)

This a continuation-in-part (CIP) application based on U.S. patent application Ser. No. 18/900,184 filed Sep. 27, 2024, the disclosure which is hereby incorporated by reference in its entirety.

### FIELD OF THE INVENTION

The present invention relates to the field of electronic devices, and, more particularly, to integrated circuits and related methods.

### BACKGROUND OF THE INVENTION

A three-dimensional integrated circuit (3DIC) is an integrated circuit (IC) manufactured by stacking individual ICs vertically and interconnecting the ICs. The vertically stacked ICs may be interconnected by using, for example, through-silicon vias or copper-copper connections, for example, so that the vertically stacked interconnected ICs function as a single IC. A 3DIC may provide improved operational performance with respect to reduced power and a smaller footprint, for example, relative to a two-dimensional IC. However, a 3DIC may have relatively limited space and compatibility with relatively high input/output count to enable die to die electrical interconnects.

It may be desirable to reduce, remove, or move heat from an 3DIC. One approach for removing heat from a 3DIC includes optimization of through-substrate copper via arrays and reliance on interconnect substrate material, for example, silicon carbide and aluminum nitride. Another approach may include interlayer thermal management. For example, pyrolytic graphite sheets may be bonded to die in a stacked die configuration. While this approach showed improvement of thermal management, production challenges may make this approach less desirable. Moreover, this may not be viable for large-scale production efforts. Another approach to thermal management in a 3DIC may include the use of micro-channel pumped fluid. However, this technique is relatively complex based upon additional components, such as, for example, a pump, to enable forced liquid cooling.

A constant conductance heat pipe (CCHP), commonly referred to as a heat pipe is a passive device that includes a hermetic enclosure (typically metal to enable conductive coupling to dissipating structures/components), and a wick structure within a vapor space to provide capillary return of working fluid from the condenser section back to the evaporator. A working fluid that changes phase (e.g., liquid to vapor boiling) shuttles heat within the vapor space between an evaporator section (e.g., where heat is introduced) and a condenser section (e.g., where heat is rejected and the working fluid reverts back to a liquid).

### SUMMARY OF THE INVENTION

An integrated circuit (IC) assembly may comprise a substrate and a plurality of IC die coupled to the substrate. The substrate may comprise a bottom layer and a top layer coupled thereto and defining a heat exchange fluid chamber therebetween, a plurality of dielectric pillars extending within the heat exchange fluid chamber between the bottom layer and the top layer, a heat exchange fluid within the heat exchange fluid chamber, and a wick structure within the heat exchange fluid chamber for moving the heat exchange fluid in a liquid phase into the heat exchange fluid chamber. A plurality of electrically conductive through-vias may extend within respective ones of the plurality of dielectric pillars and are exposed on outer surfaces of the bottom layer and the top layer. An optical waveguide layer may be above the top layer.

A redistribution layer (RDL) may be between the top layer and the optical waveguide layer. The heat exchange fluid chamber, heat exchange fluid, and wick structure may define a passive thermal removal arrangement. The substrate may comprise a thermally conductive layer lining the heat exchange fluid chamber. The thermally conductive layer may comprise a nanodiamond layer or a chemical vapor deposited (CVD) diamond layer. The thermally conductive layer may comprise a metal layer.

The substrate may comprise a plurality of blind thermally conductive vias extending into at least one of the bottom layer and top layer. A heat rejection structure may be coupled to the substrate. The plurality of IC die may be laterally arranged on the substrate. The plurality of IC die may be vertically arranged on the substrate. Each of the electrically conductive through-vias may comprise at least one of copper and aluminum.

A method for making an integrated circuit (IC) assembly may comprise coupling a plurality of IC die on a substrate. The substrate may comprise a bottom layer and a top layer coupled thereto and defining a heat exchange fluid chamber therebetween, a plurality of dielectric pillars extending within the heat exchange fluid chamber between the bottom layer and the top layer, a heat exchange fluid within the heat exchange fluid chamber, and a wick structure within the heat exchange fluid chamber for moving the heat exchange fluid in a liquid phase into the heat exchange fluid chamber. A plurality of electrically conductive through-vias may extend within respective ones of the plurality of dielectric pillars and being exposed on outer surfaces of the bottom layer and the top layer, and an optical waveguide layer may be above the top layer.

### BRIEF DESCRIPTION OF THE DRAWINGS

Other objects, features and advantages of the present invention will become apparent from the detailed description of the invention which follows, when considered in light of the accompanying drawings in which:

FIG. 1 is a schematic cross-sectional diagram of an interposer for an integrated circuit (IC) in accordance with an embodiment.

FIGS. 2A-2E are schematic cross-sectional diagrams of steps in a fabrication process of making the interposer of FIG. 1.

FIG. 3 is a schematic cross-sectional diagram of a portion of the fabrication process of an interposer for an IC in accordance with another embodiment.

FIG. 4 is a schematic diagram of an IC assembly including respective interposers in accordance with an embodiment.

FIG. 5 is a schematic diagram of a portion of the IC assembly of FIG. 4 illustrating electrical interconnection between adjacent stacked die and the respective interposer.

FIG. 6 is a sectional view of another embodiment of the integrated circuit (IC) assembly having an optical waveguide layer and IC die laterally arranged on the substrate in accordance with an embodiment.

FIG. 7 is an enlarged schematic cross-sectional view of the substrate and optical waveguide layer in the IC assembly of FIG. 6.

FIG. 8 is a top plan view in section of the IC assembly of FIG. 6 showing a portion of the redistribution layer (RDL).

FIGS. 9A-9G are schematic cross-sectional diagrams of steps in the fabrication process of making the substrate of FIG. 6.

FIG. 10 is a sectional view of another embodiment of the IC assembly similar to that shown in FIG. 6, but having a plurality of IC die vertically arranged on the substrate.

### DETAILED DESCRIPTION

The present description is made with reference to the accompanying drawings, in which exemplary embodiments are shown. However, many different embodiments may be used, and thus, the description should not be construed as limited to the particular embodiments set forth herein. Rather, these embodiments are provided so that this disclosure will be thorough and complete. Like numbers refer to like elements throughout, and prime notation is used to indicate similar elements in different embodiments.

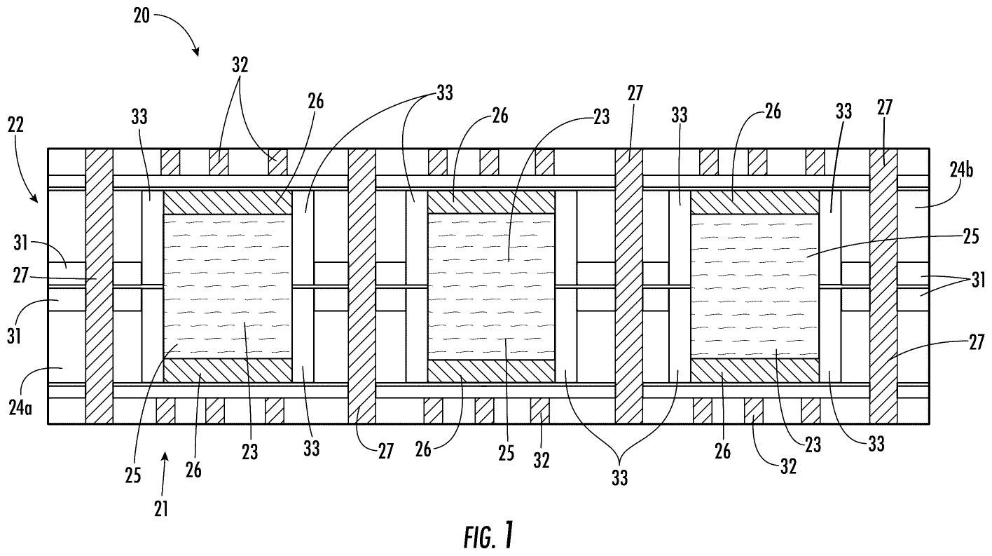

Referring initially to FIG. 1, an interposer 20 for an integrated circuit (IC) device includes an interposer bottom 21 and an interposer top 22 coupled to the interposer bottom. The interposer bottom 21 may include one of glass and quartz, for example. The interposer top 22 may also include one of glass and quartz, for example. The glass and/or quartz may have a coefficient of thermal expansion (CTE) set to, or match, the CTE of other components, as will be described in further detail below. The top and/or bottom interposers 21, 22 may be or include other or additional materials.

The interposer bottom 21 and the interposer top 22 together define a heat exchange fluid chamber 23 therebetween. A thermally conductive layer 33 lines the heat exchange fluid chamber 23. The thermally conductive layer 33 may include any one or more of metal and a nanodiamond layer. Of course, the thermally conductive layer 33 may include other or additional materials.

A coupling interface region 31 is between the interposer bottom 21 and the interposer top 22. The coupling interface region 31 may include silicone dioxide (SiO), for example. Further details regarding the interface region 31 are described below.

Interposer dielectric pillars 24a, 24b extend within the heat exchange fluid chamber 23 between the interposer bottom 21 and the interposer top 22. A wick structure 26 within the heat exchange fluid chamber 23 is for moving the heat exchange fluid 25 in a liquid phase into the heat exchange fluid chamber.

A heat exchange fluid 25 is within the heat exchange fluid chamber 23. As will be appreciated by those skilled in the art, the heat exchange fluid chamber 23, the heat exchange fluid 25, and the wick structure 26 together define a passive thermal removal arrangement, for example, to remove heat. The heat exchange fluid chamber 23, the heat exchange fluid 25, and the wick structure 26 together define a heat pipe arrangement that has increased mechanical and thermal performance (e.g., tailored coefficient of thermal expansion (CTE)).

Electrically conductive through-vias 27 extend within respective ones of the interposer dielectric pillars 24a, 24b. The electrically conductive through-vias 27 are exposed on outer surfaces of the interposer bottom 21 and the interposer top 22. The electrically conductive through-vias 27 may be copper and/or aluminum, for example. The electrically conductive through-vias 27 may be another material or include other materials, for example, with increased thermal performance, as will be appreciated by those skilled in the art.

Blind thermally conductive vias 32 extend into the interposer top 22 and the interposer bottom 21. While the blind thermally conductive vias 32 extend into the interposer top 22 and interposer bottom 21, those skilled in the art will appreciate that the blind thermally conductive vias may extend into either the interposer top or interposer bottom. In some embodiments, the interposer 20 may not include blind thermally conductive vias 32.

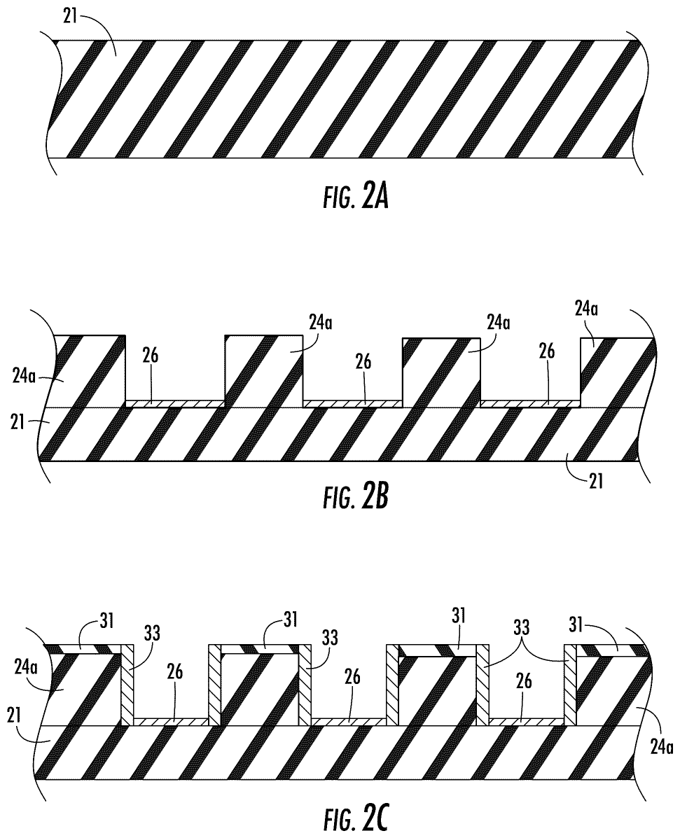

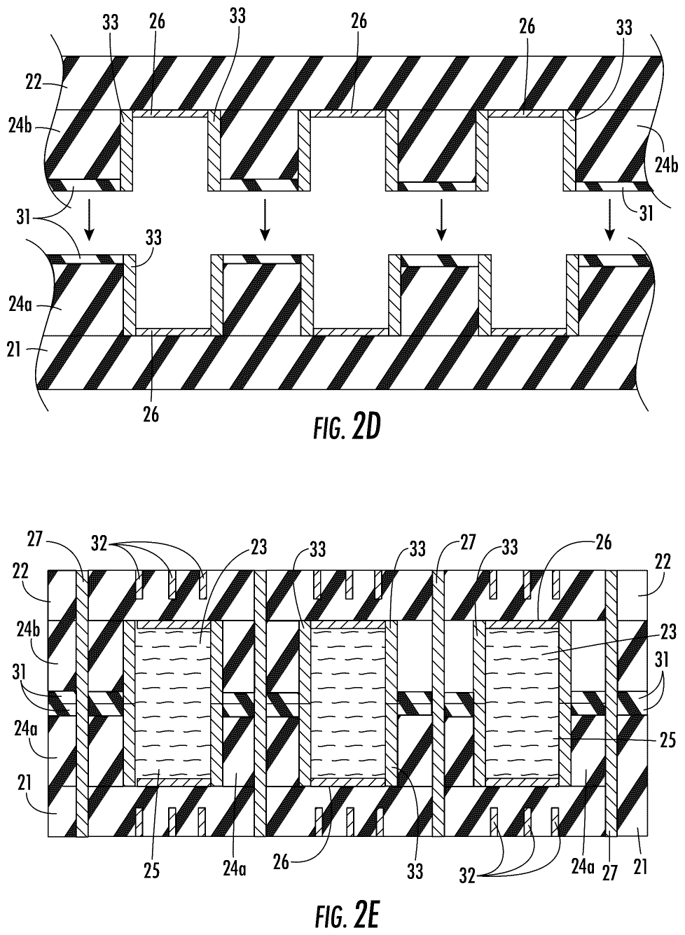

Referring now to FIGS. 2A-2E, further details of the interposer 20 will be described with reference to an exemplary fabrication process. The interposer bottom 21, for example, in the form of a quartz wafer (FIG. 2A), is laser irradiated to create bottom interposer dielectric pillars 24a, for example, defining part of an internal wick topology. A femtosecond laser may be used to provide the laser irradiation. The interposer bottom 21 is chemically etched to remove weakened material created by the laser irradiation process. This combination of the femtosecond laser irradiation and chemical etching defines a FLICE process. FLICE is a process whereby first a transparent material is irradiated with a femtosecond laser at its focal point, breaking bonds and weakening certain areas, for example, to permit three-dimensional (3D) topologies to be formed.

“FLICE stops,” or light blocking materials, can be used to more finely control end points during the laser irradiation process. The weakened areas created by the laser irradiation are chemically and selectively etched relative to the non-weakened areas to create the desired 3D topology.

The resultant interposer bottom 21 includes interposer dielectric pillars 24a (e.g., glass) and an etched wick structure 26 (FIG. 2B). The above described FLICE operations are performed on the interposer top 22 so that the interposer top is a duplicate of the interposer bottom 21 including top interposer dielectric pillars 24b (FIG. 2D). The thermally conductive layer 33 is applied to the interposer bottom 21 and the interposer top 22 to create, for example, a metallized wick structure 26 (FIGS. 2C and 2D) (e.g., formed based upon FLICE operations). The thermally conductive layer 33 may be applied by way of a physical vapor deposition (PVD), for example. In embodiments where the thermally conductive layer 33 is in the form of a nanodiamond layer, the thermally conductive layer may be deposited via electrophoretic deposition, for example. As will be appreciated by those skilled in the art, the thermally conductive layer 33 is compatible with the target substrate and may provide improved lateral conduction within the heat exchange fluid chamber 23 and thru-plane conductive coupling from the heat source to the heat exchange fluid 25.

Bonding operations are performed (FIG. 2D). For example, the surfaces of the bottom and top interposers 21, 22 are planarized (e.g., ˜<0.5 nm surface root mean square (RMS) roughness), subject to an oxide deposition, for example SiO₂, and then planarized again (e.g., using a chemical mechanical polish (CMP) process). Plasma activation is performed and the interposer bottom 21 and interposer top 22 are bonded together or mated, for example, joining deposited SiO₂ (FIGS. 2D and 2E). The plasma activation may be followed by deionized (DI) wafer rinse an Ne drying processes. The plasma activation process may define the coupling interface region 31. Bond strength may be improved by annealing with a temperature greater than 200° C., for example. The heat exchange fluid chamber 23 is defined upon the mating. The heat exchange fluid chamber 23 may be define a hermetic vapor space, for example, for the heat exchange fluid 25.

Once the interposer bottom 21 and interposer top 22 are bonded, the electrically conductive through-vias 27 and blind thermally conductive vias 32 are formed, first by forming the openings that define these vias. As will be appreciated by those skilled in the art, the blind thermally conductive vias 32 may provide increased through-plane conduction to the vapor space or heat exchange fluid chamber 23, while the electrically conductive through-vias 27 provide electrical input/output.

The openings are plated, for example, with a copper deposition. The openings may be plated with other and/or additional metals or materials (FIG. 2E). The vapor space or heat exchange fluid chamber 23 is filled with the heat exchange fluid 25 (FIG. 2E). During operations, the wick structure 26 within the vapor space or heat exchange fluid chamber 23 provides capillary return of the heat exchange fluid 25 from a condenser or heat sink section back to an evaporator or heat generator.

Referring now briefly to FIG. 3, in another embodiment, the interposer bottom 21′ may be lasered and etched while the interposer top 22′ may not be lasered and etched. The etched interposer bottom 21′ may thus be bonded to the non-etched interposer to define the heat exchange fluid chamber 23′. In other words, the interposer dielectric pillars 24′ extend within the heat exchange fluid chamber 23′ based upon etching of the interposer bottom 21′. The wick structure 26′, electrically conductive through-vias, blind thermally conductive vias, thermally conductive layer 33′, and the coupling interface region 31′ are similar to the embodiment described above. Of course, in some embodiments, the interposer bottom 21′ and interposer top 22′ may be reversed such that the interposer top may be lasered and etched while the interposer bottom 21′ may not be lasered and etched.

Decreasing size, weight, and power (SWaP) in electronics typically results in the packing of a higher density of heat producing electronics in a smaller space. For 3DICs in particular, this problem may typically be compounded by stacking of die in the vertical dimension, creating additional thermal resistances for interior die to transport heat to the package. Removal of this heat relatively quickly becomes a factor in the ability to successfully miniaturize electronics. The interposer 20 provides an approach to increase heat removal. As will be understood by those skilled in the art, the interposer 20 may provide thermally optimized wick structures by tailoring enclosure material conductivity (metal or nano-particle deposition). The interposer 20 may also provide the capability of enhancing conductive coupling between the heat generating source and the heat exchange fluid based upon, for example, a hermetic, constant conductance heat pipe (CCHP). Thus, the interposer 20 may provide between 5 and 50 times greater effective conductivity versus other approaches, for example, diamond as a heat transfer material.

A method aspect is directed to a method of making an interposer 20. The method includes coupling an interposer bottom 21 to an interposer top 22 to define a heat exchange fluid chamber 23 therebetween and forming a plurality of interposer dielectric pillars 24a, 24b extending within the heat exchange fluid chamber between the interposer bottom and the interposer top. The method also includes forming a heat exchange fluid 25 within the heat exchange fluid chamber 23 and forming a wick structure 26 within the heat exchange fluid chamber for moving the heat exchange fluid in a liquid phase into the heat exchange fluid chamber. The method further includes forming a plurality of electrically conductive through-vias 27 extending within respective ones of the plurality of interposer dielectric pillars 24a, 24b and being exposed on outer surfaces of the interposer bottom 21 and the interposer top 22.

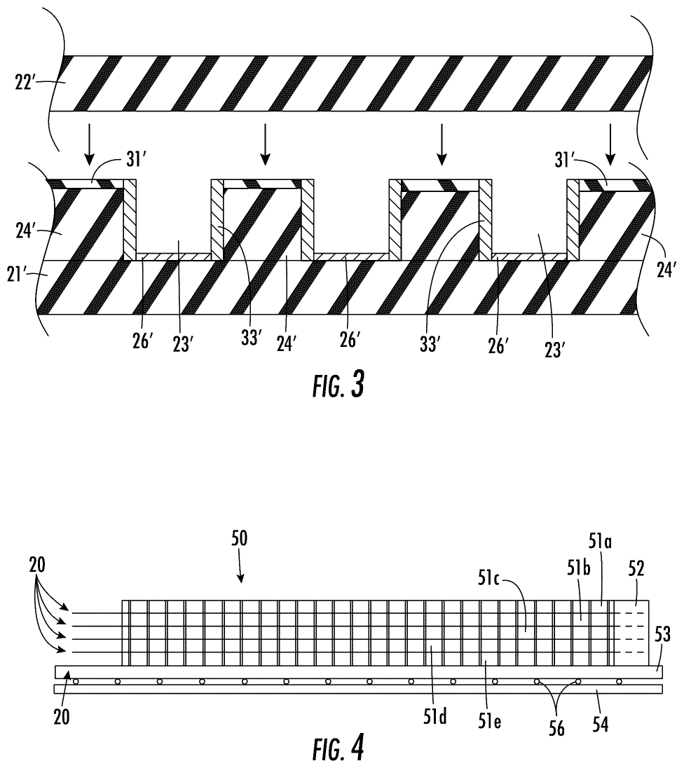

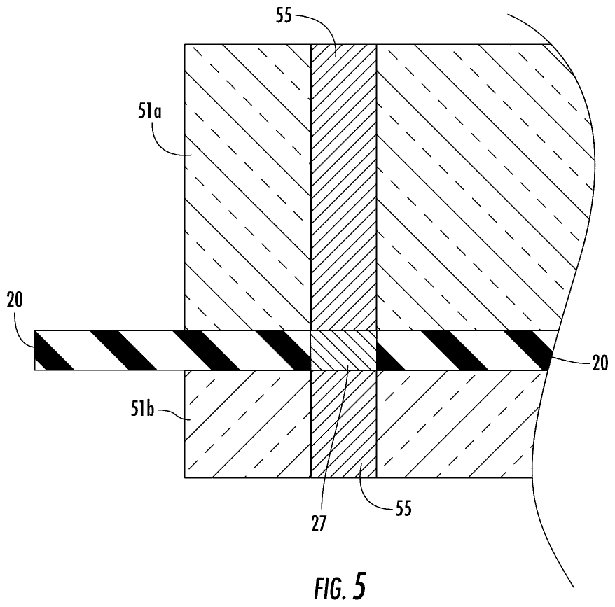

Referring now to FIG. 4, the interposer 20 may be particularly advantageous for use within IC assembly 50, for example, a 3DIC. More particularly, an exemplary IC assembly 50 includes stacked IC die 51a-51e. While five stacked IC die 51a-51e are illustrated, those skilled in the art will appreciate that there may be any number of stacked IC die.

A respective interposer 20 is between, for example, bonded between, adjacent ones of the stacked die 51a-51e. While five stacked die 51a-51e are illustrated there may be any number of stacked die. Each interposer 20 is similar to those described in the embodiments above.

Each interposer 20 is compatible with wafer-to-wafer or die-to-wafer processing within existing 3DIC fabrication infrastructure. For example, SiO₂ may be deposited onto a bonding surface of each interposer 20. The bond surface of the interposer 20 may be thermally enhanced by the blind thermally conductive vias. Chemical mechanical polishing (CMP) may be performed to each wafer or stacked die 51a-51e. Top and bottom side oxide deposition may be desirable for certain multi-stack 3DIC arrangements. The wafers or stacked die 51a-51e may be joined using DBI® process technology (direct bond interconnect). As will be appreciated by those skilled in the art, annealing may cause both electrical through-vias and thermal blind vias to expand metallic pillars to form interconnects. Other interconnect processes, such as, for example, thermocompression bonding or solder bonding may be used. Indeed, while both stacked wafers and stacked die 51a-51e are described, those skilled in the art will appreciate that an integrated wafer may be singulated.

Referring additionally and briefly to FIG. 5, with respect to the electrical interconnects, each stacked die 51a-51e includes a through-substrate via 55. The through-substrate vias 55 are aligned with the electrically conductive through-vias 27 (i.e., through-glass vias) to form electrical interconnects therewith. Accordingly, electrical interconnect, e.g., high-density interconnect (HDI) is enabled by the electrically conductive through-vias 27 bridging die-to-die (through-substrate) connections or vias 55. In an embodiment, the through-substrate vias 55 may be offset from the electrically conductive through-vias 27 by way of redistribution layer (RDL) routing therebetween.

Referring again to FIG. 4, an electrical substrate 53 carries the stacked die 51a-51e and respective interposers 20. A printed circuit board (PCB) 54 is coupled to the electrical substrate 53. More particularly, the PCB is coupled to a bottom side of the electrical substrate 53 by way of a coupling arrangement, such as, for example, a ball grid array 56. The stacked die 51a-51e and respective interposers 20 are carried by a top side of the electrical substrate 53.

A heat rejection structure 52 is adjacent the stacked die 51a-51e and the respective interposers 20. The heat rejection structure 52 is carried by the electrical substrate adjacent the stacked die 51a-51e. The heat rejection structure 52 may be considered a secondary heat rejection structure, as the interposers 20 may be considered a primary heat rejection or removal structure for the IC assembly 50.

As will be appreciated by those skilled in the art, the interposers 20 are mechanically, thermally and electrically joined to adjacent die wafers 51a-51e (or singulated dice) to form a fully functional 3-dimensional integrated circuit (3DIC) or IC assembly 50. The IC assembly 50 provides integral passive thermal management for the acquisition and transport of waste heat to the periphery of the die stack, for example to the heat rejection structure 52.

Indeed, the IC assembly 50 may permit integration of a form of passive, constant conductance heat pipe (CCHP) technology into stacked die architectures. The IC assembly 50 may provide between 5 and 50 times greater effective conductivity versus diamond, for example, and may be compatible with relatively low loss substrate material, e.g., coefficient of thermal expansion (CTE) matched material (quartz/glass). As will be appreciated by those skilled in the art, the CTE of glass, for example, may be tuned through different additives, while quartz, for example, naturally has a relatively low CTE. The IC assembly 50 may also provide the capability of using 1 or N interposers 20 between adjacent die 51a-51e depending on the desired use case.

Moreover, the IC assembly 50 may be considered to be compatible with industry standard wafer-processing technology, can be offered as a commercial off-the-shelf (COTS) solution with what is considered a standard pitch or in custom configurations. The IC assembly 50 also, as described above, enables HDI between adjacent ones of the stacked die 51a-51e and does so without additional three-dimensional subtractive structures in inorganic (i.e., wafer) materials, as the wick structure formation using deep reactive ion etching (DRIE) is constrained to two dimensions.

A method aspect is directed to a method of making an IC assembly 50. The method includes coupling a respective interposer 20 between adjacent ones of a plurality of stacked IC die 51a-51e. Each interposer 20 may include an interposer bottom 21 and an interposer top 22 coupled thereto and defining a heat exchange fluid chamber 23 therebetween and a plurality of interposer dielectric pillars 24a, 24b extending within the heat exchange fluid chamber between the interposer bottom and the interposer top. Each interposer includes a heat exchange fluid 25 within the heat exchange fluid chamber 23 and a wick structure 26 within the heat exchange fluid chamber for moving the heat exchange fluid in a liquid phase into the heat exchange fluid chamber. Each interposer includes a plurality of electrically conductive through-vias 27 extending within respective ones of the plurality of interposer 24a, 24b and being exposed on outer surfaces of the interposer bottom 21 and the interposer top 22.

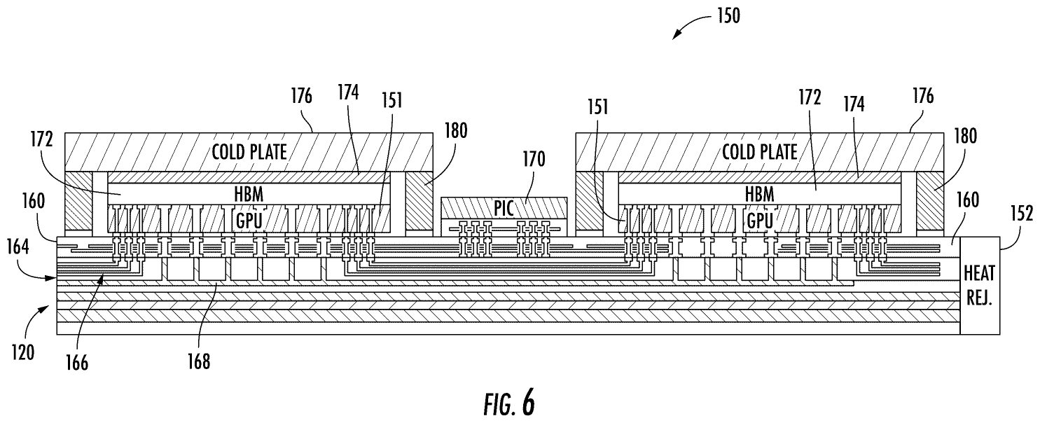

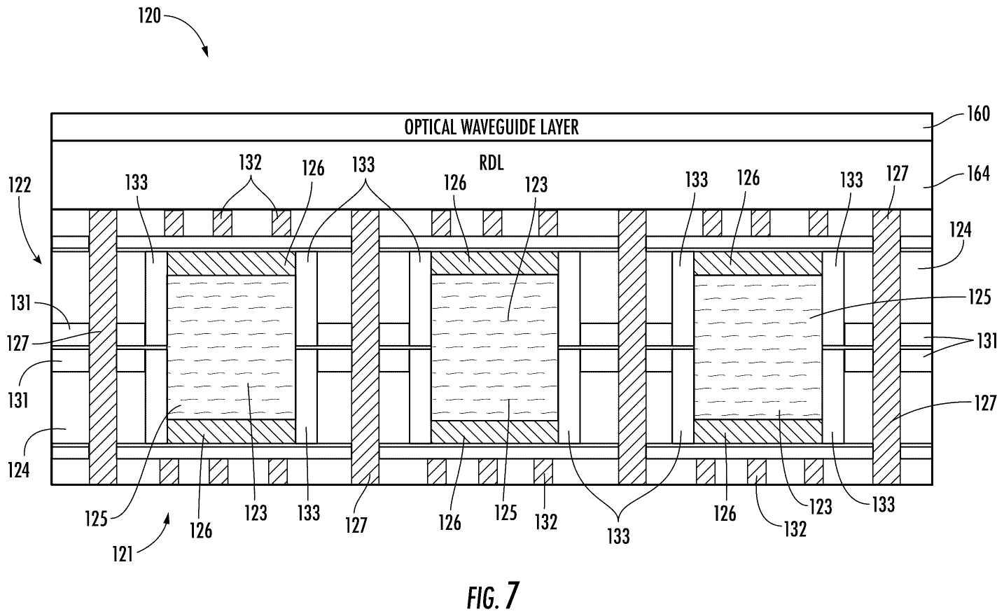

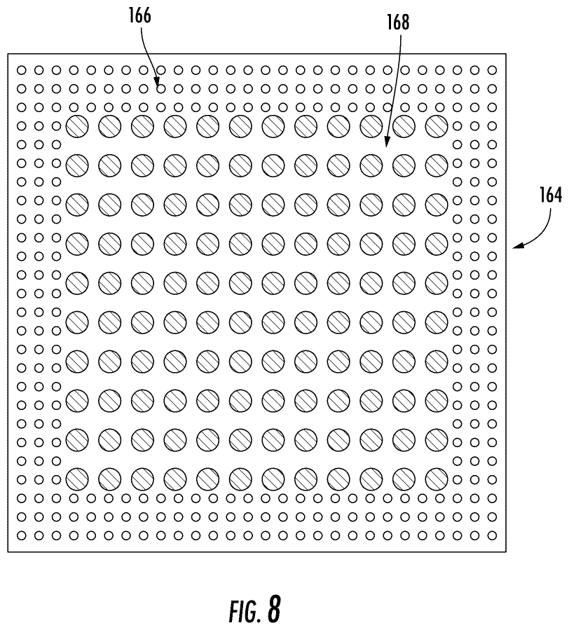

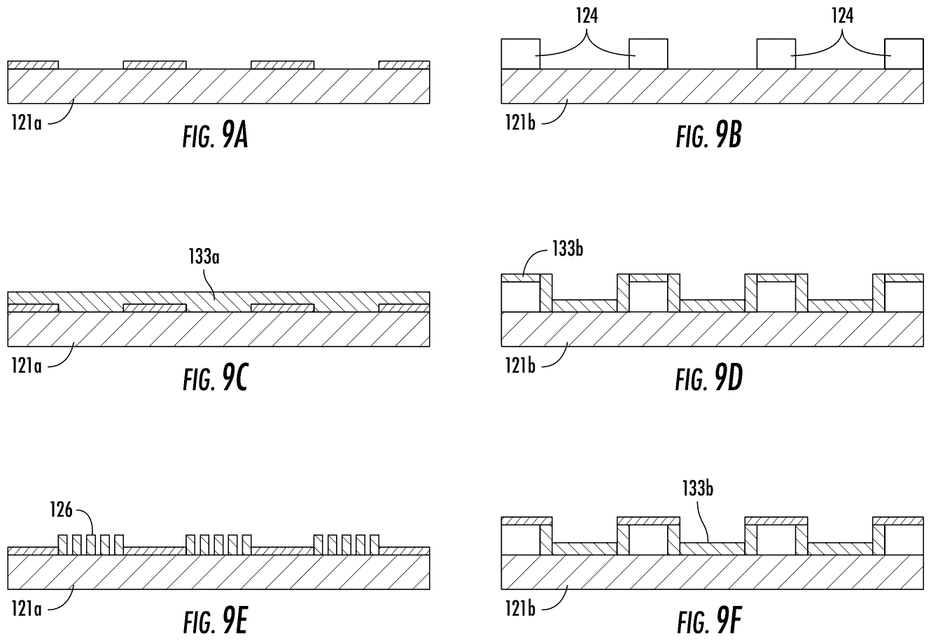

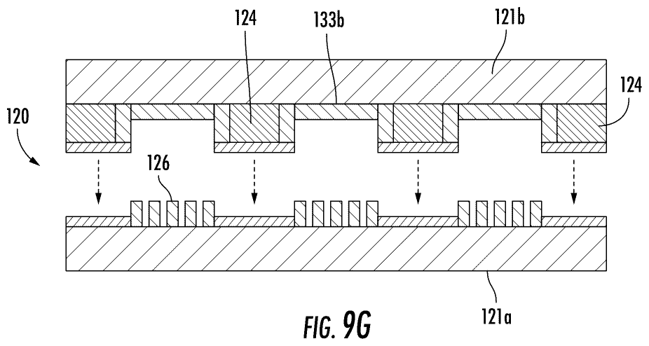

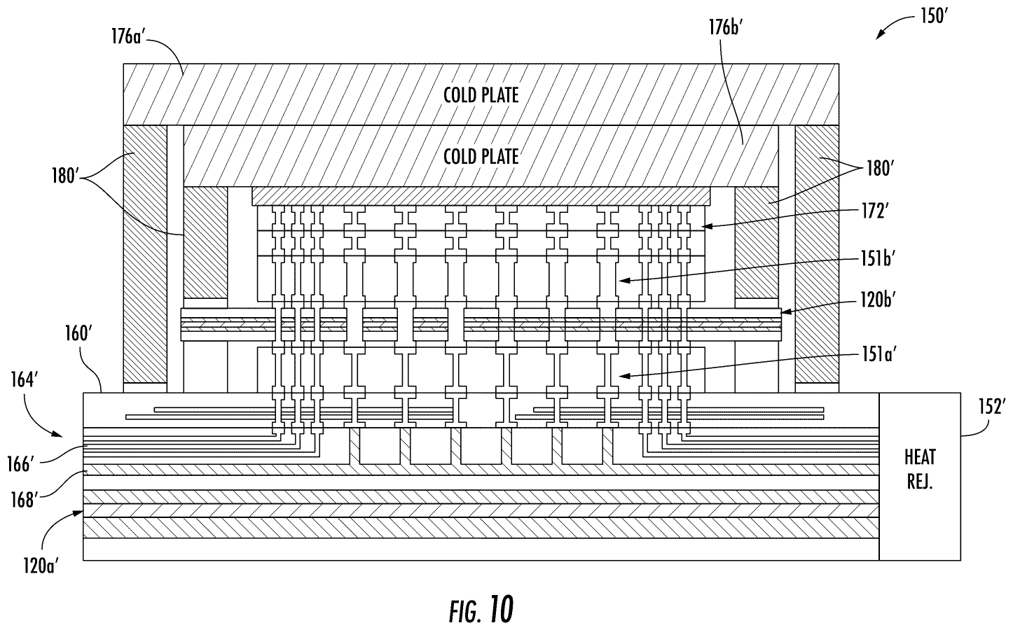

Referring now to FIGS. 6 and 7, there is illustrated an embodiment of the integrated circuit (IC) assembly 150 that includes a substrate 120 formed similar to the interposer as described with reference to FIGS. 1-5, with a bottom layer 121 and top layer 122 coupled thereto and defining a heat exchange fluid chamber 123 therebetween (FIG. 7). In this embodiment of the IC assembly 150, an optical waveguide layer 160 is above the top layer 122 of the substrate 120. For consistency, the same reference numerals as described with reference to FIGS. 1-5 are used for common elements of the IC assembly 150, but in the 100 series for that embodiment shown in FIGS. 6-8, and in the 100′ series for the embodiment of the IC assembly 150′ shown in FIG. 9. A plurality of IC die 151 are coupled to the substrate 120. The plurality of IC die 151 are laterally arranged on the substrate 120 in the IC assembly 150 embodiment of FIGS. 6-8, but the plurality of IC die 151′ are vertically arranged on the substrate 120′ in the embodiment of the IC assembly 150′ shown in FIG. 9.

As shown in the sectional view of FIG. 6 for the IC assembly 150, and more particularly the schematic cross-sectional view of the substrate 120 and optical waveguide layer 160 in FIG. 7, the substrate not only includes the bottom layer 121 and top layer 122, and the heat exchange fluid chamber 123 defined therebetween, but also the plurality of dielectric pillars 124 that extend within the heat exchange fluid chamber between the bottom layer and top layer. A heat exchange fluid 125 is within the heat exchange fluid chamber 123. A wick structure 126 similar to that described with reference to the interposer 20 and IC assembly 50 of FIGS. 1-5 is contained within the heat exchange fluid chamber 123 for moving the heat exchange fluid 125 in a liquid phase into the heat exchange fluid chamber.

A plurality of electrically conductive through-vias 127 extends within respective ones of the plurality of dielectric pillars 124 and are exposed on outer surfaces of the bottom layer 121 and the top layer 122.

The heat exchange fluid chambers 123, heat exchange fluid 125, and wick structures 126 define a passive thermal removal arrangement. The substrate 120 includes a thermally conductive layer 133 lining the heat exchange fluid chamber 123 as described above with reference to FIGS. 1-5. In an example, this thermally conductive layer 133 may be formed as a nanodiamond layer or a chemical vapor deposited (CVD) diamond layer, and in another example, may be a metal layer. It is possible to form the thermally conductive layer 133 with about 10 microns up to about 25 microns of nanodiamond layer for more efficient heat transfer capabilities. A coupling interface region 131 is between the bottom layer 121 and top layer 122 and may be defined by the plasma activation process described in the exemplary fabrication process with reference to FIGS. 2A-2E. The substrate 120 includes a plurality of blind

thermally conductive vias 132 that extend into at least one of the bottom layer 121 and the top layer 122. The electrically conductive through-vias 127 may be formed of at least one of copper and aluminum. A heat rejection structure 152 is adjacent coupled to the substrate 120.

The IC assembly 150 is a high volume manufactured, compatible wafer-scale system architecture that may be part of a microfabrication process flow to create a two-phase chip-level thermal solution that can function as either an interlayer, such as the interposer 20 described with reference to FIGS. 1-5, or a separate substrate 120 for a wafer-scale architecture of multiple die 151 as in the IC assembly 150 of FIGS. 6-8. In this example, a redistribution layer (RDL) 164 is between the top layer 122 and the optical waveguide layer 160 and forms input/output wiring and connection pads to the plurality of IC die 151 and other circuits as shown in the top plan and partial section view of the IC assembly 150 in FIG. 8, where fine-pitch signal I/O 166, power delivery I/O 168 and associated connectors are shown.

In the example of FIG. 6, the optical waveguide layer 160 above the top layer 122 provides the optical link for the plurality of IC die 151 and associated circuits, and receives any optical signals generated from a laser (not shown) or other optical source. A photonic integrated circuit (PIC) 170 is connected to the optical waveguide layer 160 and interconnects the redistribution layer 164 and connects to the plurality of IC die 151. In this example, the plurality of IC die 151 are formed as the illustrated graphical processing unit (GPU) operative with a high bandwidth memory (HBM) 172 circuit that is coupled via a thermal interface layer 174 with a cold plate 176 to help draw heat away from the associated IC die as the GPU 151, the HBM 172, and other circuits. Thermal support members 180 may help support the cold plates 176. The optical waveguide layer 160 provides an optical path for the optical signals to and from the photonic integrated circuit 170 and the plurality of IC die 151 for optical signal routing in a large compute system that contains the plurality of IC die 151.

Referring now to FIGS. 9A-9G, further details of the substrate 120 will be described with reference to an exemplary fabrication process. The description relative to FIGS. 2A-2E described the FLICE process for forming the dielectric pillars 24 and wick structure 26 topologies described in those figures. The example of the fabrication process shown in FIGS. 9A-9G is another, more wafer-scale compatible process to form the internal surfaces of mating wafers as top and bottom substrate segments that integrate to form the first substrate 120 shown, for example, in FIG. 6. These figures illustrate that certain operations may occur on one of the mating substrate halves, while different operations occur on the other mating half.

In this example, FIGS. 9A, 9C and 9D correspond to one side or half of the substrate 120, while FIGS. 9B, 9D and 9F correspond to the opposing side or half of the substrate 120, shown completed in FIG. 9G. This process is fully wafer-scale microfabrication compatible with high volume manufacturing. The dielectric pillars 124 in one half of the process shown in FIGS. 9B, 9D and 9F may be formed using deep reactive ion etching (DRIE) as a plasma-based process that creates deep, steep-sided trenches and holes for the substrate as compared to using FLICE process as in the process as shown in FIGS. 2A-2E.

In the description, the left half of the figures showing FIGS. 9A, 9G and 9E correspond to the bottom half as non-limiting examples, and FIGS. 9B, 9D and 9F correspond to the top half. In FIG. 9A, a silicon dioxide (SiO) base as a separate bottom substrate segment 121a is patterned. This bottom half formed as the separate bottom substrate segment 121a may be silicon, glass or quartz. Other alternative bottom substrate segments 121a may be selected. In FIG. 9B showing the top substrate segment 121b, the pillars 124 are deep etched such as using DRIE. This top substrate segment 121b also could be formed from silicon, glass or quartz.

In FIG. 9C, a bottom nano-diamond layer 133a that later forms the thermal interface layer 133 is deposited or may be patterned as a diamond wafer. In FIG. 9D, a top nano-diamond layer 133b may be electrophoretic deposited (EPD). In that process, an electric field may be applied between conductive portions that operate as electrodes, and the charged particles in a liquid medium move toward oppositely charged conductive portions as electrodes. The particles are deposited on the surface of the electrodes, forming the coating. In FIG. 9E, the pattern with wicks structure 126 are formed such as from etching the nano-diamond layer or coating on the prior etched and patterned silicon bottom substrate segment 121a, with similar features. In FIG. 9F, a chemical mechanical polishing (CMP) process is followed with a silicon dioxide layering and further chemical mechanical polishing. In FIG. 9G, the substrate 120 is formed by hybrid bonding the top substrate segment 121b to the bottom substrate segment 121a to form vapor spaces.

In another example, the plurality of IC die 151′ are vertically arranged in a stacked configuration, such as shown in the IC assembly 150′ of FIG. 10. As illustrated in that sectional view of the IC assembly 150′, a first IC die 151a′ as an example graphical processing unit (GPU) is positioned over a first substrate 120a′ and the RDL 164′ and optical waveguide 160′. A second IC die 151b′ as a GPU is stacked on the first IC die 151a′ and both are coupled to respective first and second high bandwidth memory (HBM) units forming an HBM stack 172′. A second substrate 120b′ is interposed between the first and second IC die 151a′, 151b′ as the GPU's. The various interconnects and contacts of the RDL layer 164′ also interconnect to the first and second IC die 151a′, 151b′ as the GPU's. Although two stacked IC die 151a′, 151b′ are illustrated, a larger number of IC die may be stacked. First and second cold plates 176a′, 176b′ are stacked with each other. The first cold plate 176a′ is coupled to the first substrate 120a′ and the second cold plate 176b′ is coupled to the second substrate 120b′ to permit heat transfer via thermal support members 180′ to aid in drawing heat away from the substrates 120a′, 120b′. Similar to the IC assembly 150 of FIG. 6, a heat rejection structure 152′ is adjacent coupled to the first substrate 151a′.

A method for making the IC assembly 150, 150′ shown in FIGS. 6-10 is now described. The substrate 120, 120a′, 120b′ is formed by forming the bottom layer 121, 121′ and top layer 122, 122′ coupled thereto and defining the heat exchange fluid chamber 123, 123′ therebetween, and plurality of dielectric pillars 124, 124′ extending within the heat exchange fluid chamber. A wick structure 126, 126′ is formed within the heat exchange fluid chamber 123, 123′ and a plurality of electrically conductive through-vias 127, 127′ extend within respective ones of the plurality of dielectric pillars 124, 124′ and are exposed on outer surfaces of the bottom layer 121, 121′ and the top layer 122, 122′. An optical waveguide layer 160, 160′ is formed above the top layer 122, 122′. A heat exchange fluid 125, 125′ is inserted within the heat exchange fluid chamber 123, 123′. A plurality of IC die 151, 151a′, 151b′ are coupled to the substrate 120, 120′ and the process ends. The fabrication process described for the IC assembly 50 of FIG. 4 may be employed for the fabrication process of the IC assembly 150, 150′.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. An integrated circuit (IC) assembly comprising:
a substrate and a plurality of IC die coupled to the substrate;
the substrate comprising
a bottom layer and a top layer coupled thereto and defining a heat exchange fluid chamber therebetween,
a plurality of dielectric pillars extending within the heat exchange fluid chamber between the bottom layer and the top layer,
a heat exchange fluid within the heat exchange fluid chamber,
a wick structure within the heat exchange fluid chamber for moving the heat exchange fluid in a liquid phase into the heat exchange fluid chamber,
a plurality of electrically conductive through-vias extending within respective ones of the plurality of dielectric pillars and being exposed on outer surfaces of the bottom layer and the top layer, and
an optical waveguide layer above the top layer.

2. The IC assembly of claim 1 comprising a redistribution layer (RDL) between the top layer and the optical waveguide layer.

3. The IC assembly of claim 1 wherein the heat exchange fluid chamber, heat exchange fluid, and wick structure define a passive thermal removal arrangement.

4. The IC assembly of claim 1 wherein the substrate comprises a thermally conductive layer lining the heat exchange fluid chamber.

5. The IC assembly of claim 4 wherein the thermally conductive layer comprises a nanodiamond layer.

6. The IC assembly of claim 4 wherein the thermally conductive layer comprises a metal layer.

7. The IC assembly of claim 1 wherein the substrate comprises a plurality of blind thermally conductive vias extending into at least one of the bottom layer and top layer.

8. The IC assembly of claim 1 comprising a heat rejection structure coupled to the substrate.

9. The IC assembly of claim 1 wherein the plurality of IC die is laterally arranged on the substrate.

10. The IC assembly of claim 1 wherein the plurality of IC die is vertically arranged on the substrate.

11. The IC assembly of claim 1 wherein each of the electrically conductive through-vias comprises at least one of copper and aluminum.

12. An integrated circuit (IC) assembly comprising:
a substrate and a plurality of IC die coupled to the substrate in laterally spaced relation;
the substrate comprising
a bottom layer and a top layer coupled thereto and defining a heat exchange fluid chamber therebetween,
a plurality of dielectric pillars extending within the heat exchange fluid chamber between the bottom layer and the top layer,
a heat exchange fluid within the heat exchange fluid chamber,
a wick structure within the heat exchange fluid chamber for moving the heat exchange fluid in a liquid phase into the heat exchange fluid chamber,
a nanodiamond layer lining the heat exchange fluid chamber,
a plurality of electrically conductive through-vias extending within respective ones of the plurality of dielectric pillars and being exposed on outer surfaces of the bottom layer and the top layer, and
an optical waveguide layer above the top layer.

13. The IC assembly of claim 12 comprising a redistribution layer (RDL) between the top layer and the optical waveguide layer.

14. The IC assembly of claim 12 wherein the heat exchange fluid chambers, heat exchange fluid, and wick structures define a passive thermal removal arrangement.

15. The IC assembly of claim 12 wherein the substrate comprises a plurality of blind thermally conductive vias extending into at least one of the bottom layer and top layer.

16. The IC assembly of claim 12 comprising a heat rejection structure coupled to the substrate.

17. A method for making an integrated circuit (IC) assembly comprising:
coupling a plurality of IC die on a substrate;
the substrate comprising
a bottom layer and a top layer coupled thereto and defining a heat exchange fluid chamber therebetween,
a plurality of dielectric pillars extending within the heat exchange fluid chamber between the bottom layer and the top layer,
a heat exchange fluid within the heat exchange fluid chamber,
a wick structure within the heat exchange fluid chamber for moving the heat exchange fluid in a liquid phase into the heat exchange fluid chamber,
a plurality of electrically conductive through-vias extending within respective ones of the plurality of dielectric pillars and being exposed on outer surfaces of the bottom layer and the top layer, and
an optical waveguide layer above the top layer.

18. The method of claim 17 comprising coupling a redistribution layer (RDL) between the top layer and the optical waveguide layer.

19. The method of claim 17 wherein the heat exchange fluid chamber, heat exchange fluid, and wick structure define a passive thermal removal arrangement.

20. The method of claim 17 wherein the substrate comprises a nanodiamond layer lining the heat exchange fluid chamber.

21. The method of claim 17 wherein the substrate comprises a plurality of blind thermally conductive vias extending into at least one of the bottom layer and top layer.

22. The method of claim 17 comprising coupling a heat rejection structure to the substrate.

23. The method of claim 17 wherein the plurality of IC die is laterally arranged on the substrate.

24. The method of claim 17 wherein the plurality of IC die is vertically arranged on the substrate.

25. The method of claim 17 wherein the substrate comprises a metal layer lining the heat exchange fluid chamber.

26. The method of claim 17 comprising forming the plurality of dielectric pillars by deep-reactive ion etching (DRIE) the dielectric pillars on the top layer of the substrate at the surface lining the heat exchange fluid chamber.

27. The method of claim 26 comprising electrophoretically depositing (EPD) a nanodiamond layer onto the dielectric pillars at the top layer of the substrate.

28. The method of claim 17 comprising patterning the bottom layer of the substrate at the surface lining the heat exchange fluid chamber, and forming the nanodiamond layer thereon.

29. The method of claim 28 wherein forming the nanodiamond layer comprises at least one of depositing a nanodiamond layer and patterning a diamond wafer.

30. The method of claim 28 wherein the wick structure is formed by patterning wicks within the nanodiamond layer at the bottom layer of the substrate.

31. The method of claim 17 comprising hybrid bonding the top layer to the bottom layer to form the heat exchange fluid chamber therebetween.
